(19) United States
(12) Patent Application Publication
(10) Pub. No.: US 2023/0411142 A1
(43) Pub. Date: Dec. 21, 2023

(54) METAL OXIDE PRECLEANING PRIOR TO METAL FILLING

(71) Applicant: Tokyo Electron Limited, Tokyo (JP)

(72) Inventors: Ryota Yonezawa, Albany, NY (US); Kai-Hung Yu, Albany, NY (US); Tadahiro Ishizaka, Nirasaki City (JP); Atsushi Gomi, Nirasaki City (JP); Hidenao Suzuki, Albany, NY (US)

(21) Appl. No.: 18/198,355

(22) Filed: May 17, 2023

Related U.S. Application Data
(60) Provisional application No. 63/352,799, filed on Jun. 16, 2022.

(51) Int. Cl. H01L 21/02; H01L 21/3205

(52) U.S. Cl. CPC H01L 21/02068; H01L 21/32051

(57) ABSTRACT

Improved process flows and methods are provided for processing a semiconductor substrate have exposed dielectric and metal-containing surfaces. More specifically, improved process flows and methods are provided for pre-cleaning the metal-containing surfaces prior to depositing a metal material onto the metal-containing surfaces. Hot vapor-phase etching is used to remove a native oxide film from the metal-containing surfaces. Prior to hot vapor-phase etching, the semiconductor substrate is exposed to a first silicon-containing gas to deposit an inhibitor film onto the exposed dielectric and metal-containing surfaces. The inhibitor film protects the dielectric surfaces while the native oxide film is being removed via the hot vapor-phase etching. In some embodiments, the semiconductor substrate is exposed to a second silicon-containing gas, after hot vapor-phase etching, to remove residues of the hot vapor-phase etching process from the pre-cleaned metal-containing surfaces.

This application claims priority to U.S. Provisional Patent Application Ser. No. 63/352,799, filed Jun. 16, 2022, entitled “METAL OXIDE PRECLEANING PRIOR TO METAL FILLING”; the disclosure of which is expressly incorporated herein, in its entirety, by reference.

### TECHNICAL FIELD

This invention relates generally to semiconductor fabrication, and more specifically, to the processing and surface preparation of semiconductor substrates. In particular, this invention relates to methods and processes for pre-cleaning metal oxides from metal-containing surfaces prior to metal filling.

### BACKGROUND

Semiconductor devices contain recessed features (such as trenches, vias or contacts) that are formed within a dielectric material, such as an interlayer dielectric (ILD), and filled with a metal material. Selective metal filling of the recessed features is challenging for various reasons.

One challenge involved with selective metal filling of recessed features is surface cleaning prior to metal deposition. Particular surface conditions are needed to grow or deposit a given metal on a given surface successfully. For example, prior to ruthenium (Ru) deposition on a target metal surface, such as a titanium nitride (TiN) surface, it is important to pre-clean the TiN surface to remove native oxide films (such as titanium oxide, TiO2) that form on the TiN surface. Plasma cleaning is one technique that is commonly used to clean native oxide films from metal-containing surfaces prior to metal deposition. For example, a capacitively coupled plasma (CCP) or radical hydrogen plasma can be used for pre-cleaning native oxide films from metal-containing surfaces. Unfortunately, plasma cleaning processes often cause damage to the structure profile and/or uncovered dielectric materials, such as low-k materials.

FIG. 1 (Prior Art) illustrates a conventional process flow 100 that utilizes a plasma-based cleaning technique to remove native oxide films from metal-containing surfaces. The conventional process flow 100 shown in FIG. 1 is performed on a substrate having recessed feature(s) 105 formed within a dielectric material 110. A first metal material 115, having a native oxide film 120 formed thereon, is formed at the bottom of the recessed feature(s) 105. Before filling the recessed feature(s) 105 with a second metal material 125, the surface of the substrate shown in FIG. 1 is exposed to a plasma (e.g., a CCP or radical hydrogen plasma) to remove the native oxide film 120 from the first metal material 115 via dry etching. As shown in FIG. 1, the plasma process used to clean the first metal material 115 can result in undesirable rounding of the dielectric structures and/or other damage.

Improved process flows and methods are needed to remove native oxide films from metal-containing surfaces without plasma-based damage.

### SUMMARY

The present disclosure provides improved process flows and methods for processing a semiconductor substrate. More specifically, the present disclosure provides improved process flows and methods for pre-cleaning a metal-containing surface prior to depositing a metal material onto the metal-containing surface. In some embodiments, the improved process flows and methods described herein may be used to remove a native oxide film from a metal-containing surface, which may be provided at the bottom of recessed feature(s) formed within a dielectric material (such as an interlayer dielectric (ILD)). It is recognized, however, that the techniques disclosed herein are not strictly limited to any particular semiconductor structure or device and may be utilized to pre-clean a wide variety of metal-containing surfaces formed on a semiconductor substrate having, for example, both dielectric and metal-containing surfaces exposed on the substrate.

In the present disclosure, hot vapor-phase etching is used to remove the native oxide film from the metal-containing surface. Prior to hot vapor-phase etching, the substrate may be exposed to a first silicon-containing gas to deposit a silicon-containing material onto the exposed surfaces of the substrate, including exposed surfaces of the dielectric material and the native oxide film. The silicon-containing material is one, which preferentially adheres to the dielectric material, rather than the native oxide film. Thus, a substantially larger amount of the silicon-containing material is deposited onto the exposed dielectric surfaces than the native oxide film. The silicon-containing material deposited onto the exposed dielectric surfaces provides a dielectric protector or inhibitor film, which protects the dielectric material while the native oxide film (and the substantially thinner silicon-containing material overlying the native oxide film) is being removed from the metal-containing surface by the hot vapor-phase etching. In some embodiments, the substrate may be exposed to a second silicon-containing gas, after hot vapor-phase etching is used to remove the native oxide, to remove residues of the hot vapor-phase etching process from the pre-cleaned metal-containing surface.

The techniques disclosed herein provide native oxide removal without plasma-based damage. Unlike conventional process flows that utilize plasma cleaning to remove oxide films, there is only minimal damage on the dielectric surfaces after using the cleaning techniques disclosed herein. This enables the improved process flows and methods described herein to provide good metal (e.g., Ru) filling performance when the recessed feature(s) are subsequently filled with a metal material.

The techniques disclosed herein may be utilized for pre-cleaning a wide variety of metal-containing surfaces prior to depositing a wide variety of metal materials onto the metal-containing surface. In some embodiments, the techniques disclosed herein may provide sufficient cleaning on a titanium nitride (TiN) surface prior to ruthenium (Ru) deposition on the pre-cleaned TiN surface. However, the techniques disclosed herein are not limited to such example materials and can also be used to pre-clean other metal-containing surfaces prior to depositing other low-resistivity metals onto the metal-containing surfaces.

A wide variety of processing gases may be used in the pre-cleaning processes disclosed herein. In some embodiments, the techniques disclosed herein may use a combination of hot vapor hydrofluoric acid (HF) and TMSDMA (N-Trimethylsilyldimethylamine) to pre-clean a metal-containing surface. As noted above, the substrate may be exposed to TMSDMA (or another silicon-containing gas) before hot vapor HF etching to deposit a layer of TMSDMA onto exposed surfaces of the substrate to protect underlying dielectric surfaces during hot vapor etching of the native oxide film. In some embodiments, the substrate may be exposed to TMSDMA (or another silicon-containing gas) again, after hot vapor HF etching to remove residues of the hot vapor HF etching process from the pre-cleaned metal-containing surface. While hot vapor HF and TMSDMA are provided as example processing gases that can be used to pre-clean metal-containing surfaces, other hot vapor fluorine-containing agents, hot vapor chlorine-containing agents and silicon-containing gases can also be utilized in the pre-cleaning processes disclosed herein.

According to one embodiment, a method is provided herein for processing a substrate. The method may generally begin by receiving a substrate having recessed features defining regions for selective metal deposition. The recessed features, which are formed within a dielectric material, uncover a metal-containing surface having an oxide film to be removed. Next, the method may include exposing the substrate to a first silicon-containing gas to deposit a silicon-containing material on surfaces of the dielectric material by vapor-phase deposition before exposing the substrate to a vapor-phase fluorine-containing agent to remove the oxide film from the metal-containing surface. The vapor-phase fluorine-containing agent removes the oxide film from the metal-containing surface without removing the silicon-containing material deposited on the surfaces of the dielectric material. The method further includes selectively depositing a first metal on the metal-containing surface after removing the oxide film from the metal-containing surface. In some embodiments, the method may further include exposing the substrate to a second silicon-containing gas to remove fluorine residues from the metal-containing surface after said exposing the substrate to the vapor-phase fluorine-containing agent and before said selectively depositing the first metal on the metal-containing surface.

According to another embodiment, a method is provided herein for processing a substrate. The method may generally begin by receiving a substrate having recessed features defining regions for selective metal deposition. The recessed features, which are formed within a dielectric material, uncover a metal-containing surface having an oxide film to be removed. Next, the method may include depositing an inhibitor film on surfaces of the dielectric material by vapor-phase deposition before delivering a vapor-phase fluorine-containing or chlorine-containing agent to the substrate to remove the oxide film from the metal-containing surface. In some embodiments, the inhibitor film may be deposited on the surfaces of the dielectric material by exposing the substrate to a first silicon-containing gas. The inhibitor film prevents the surfaces of the dielectric material from being removed by the vapor-phase fluorine-containing or chlorine-containing agent. The method further includes selectively depositing a first metal on the metal-containing surface. In some embodiments, the method may further include exposing the substrate to a second silicon-containing gas to remove fluorine or chlorine residues from the metal-containing surface after said delivering the vapor-phase fluorine-containing or chlorine-containing agent and before said selectively depositing the first metal on the metal-containing surface.

The methods disclosed herein may expose the substrate to a wide variety of vapor-phase fluorine-containing or chlorine-containing agents to remove the oxide film from the metal-containing surface. Examples of vapor-phase fluorine-containing agents include, but are not limited to, hydrofluoric acid (HF), nitrogen trifluoride (NF3), tungsten hexafluoride (WF6) and other fluorine-containing agents. Examples of vapor-phase chlorine-containing agents include, but are not limited to, tungsten pentachloride (WCl5), hydrochloric acid (HCl), chlorine (Cl2), boron trichloride (BCl3) and other chlorine-containing agents. In some embodiments, the substrate may be held at a temperature above approximately 100 degrees Celsius during said exposing the substrate to the vapor-phase fluorine-containing or chlorine-containing agent to prevent the vapor-phase fluorine-containing or chlorine-containing agent from etching the surfaces of the dielectric material.

The methods disclosed herein may also expose the substrate to a wide variety of silicon-containing gases. For example, the first silicon-containing gas and the second silicon-containing gas may each be selected from a group comprising hexamethyldisilazane (HMDS), tetramethyldisiloxane (TMDS), dimethylsilane dimethylamine (DMSDMA), N-(Trimethylsilyl)dimethylamine (TMSDMA), bis(dimethylamino) dimethylsilane (BDMADMS), N,O-bis(trimethylsilyl)trifluoroacetamide (BSTFA), and trimethylsilane (TMS). In one embodiment, the first silicon-containing gas and the second silicon-containing gas may each include N-(Trimethylsilyl)dimethylamine (TMSDMA).

Exposing the substrate to silicon-containing gases before and after hot vapor-phase etching provides various advantages. For example, exposing the substrate to a first silicon-containing gas, prior to hot vapor-phase etching, deposits a silicon-containing material (otherwise referred to as a dielectric protector or inhibitor film) on the surfaces of the dielectric material. The silicon-containing material protects the surfaces of the dielectric material during: (a) said exposing the substrate to the vapor-phase fluorine-containing or chlorine-containing agent to remove the oxide film from the metal-containing surface, and (b) said selectively depositing the first metal on the metal-containing surface. After hot vapor-phase etching, exposing the substrate to the second silicon-containing gas restores portions of the dielectric material that are damaged during said exposing the substrate to the vapor-phase fluorine-containing or chlorine-containing agent.

The methods disclosed herein may be used to pre-clean a wide variety of metal-containing surfaces prior to depositing a metal material onto the metal-containing surface. In some embodiments, the disclosed methods may be used to remove a native oxide film from a metal-containing surface provided at the bottom of a recessed feature prior to filling the recessed feature with a low resistivity metal material. In one example implementation, the metal-containing surface may be titanium nitride (TiN), the native oxide film may be titanium oxide (TiO2), and the low resistivity metal material may be Ruthenium (Ru), Molybdenum (Mo), Cobalt (Co) or Tungsten (W). It is noted, however, that the methods disclosed herein can be used to pre-clean other metal-containing surfaces prior to depositing other metal materials thereon.

Various embodiments of methods are provided herein for processing a semiconductor substrate, and more specifically, for removing native oxide films from metal-containing surfaces provided on the substrate. Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed inventions. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 (Prior Art) is a cross-sectional view through a semiconductor substrate, illustrating a conventional process flow that utilizes a plasma-based cleaning technique to remove native oxide films from metal-containing surfaces.

FIG. 2 is a flowchart diagram illustrating one embodiment of a method that utilizes the techniques described herein to process a substrate.

FIG. 3 is a cross-sectional view through a semiconductor substrate, illustrating one example of a process flow that utilizes the techniques disclosed herein to pre-clean a metal-containing surface before selectively depositing a metal material onto the metal-containing surface.

FIG. 4 illustrates a simplified process flow that utilizes the techniques disclosed herein.

FIG. 5 is a graph illustrating an example etch rate (expressed in A/nm) of TiO2, SiO2 and other low-k dielectrics during hot vapor HF etching.

FIGS. 6(a)-6(d) are graphs of various material amounts detected on a TiO2 substrate and a SiO2 substrate during the pre-cleaning treatment described herein.

FIG. 7 is a flowchart diagram illustrating another embodiment of a method that utilizes the techniques described herein to process a substrate.

FIG. 8 is a cross-sectional view through a semiconductor substrate, illustrating another example of an improved process flow that utilizes the techniques disclosed herein to pre-clean a metal-containing surface before selectively depositing a metal material onto the metal-containing surface.

FIG. 9 shows processing details for an example semiconductor fabrication process that utilizes a plurality of modules to process a semiconductor substrate in accordance with the techniques disclosed herein.

### DETAILED DESCRIPTION

The present disclosure provides improved process flows and methods for processing a semiconductor substrate. More specifically, the present disclosure provides improved process flows and methods for pre-cleaning a metal-containing surface prior to depositing a metal material onto the metal-containing surface. In some embodiments, the improved process flows and methods described herein may be used to remove a native oxide film from a metal-containing surface, which may be provided at the bottom of recessed feature(s) formed within a dielectric material (such as an interlayer dielectric (ILD)). It is recognized, however, that the techniques disclosed herein are not strictly limited to any particular semiconductor structure or device and may be utilized to pre-clean a wide variety of metal-containing surfaces formed on a semiconductor substrate having both dielectric and metal-containing surfaces exposed on the substrate.

In the present disclosure, hot vapor-phase etching is used to remove the native oxide film from the metal-containing surface. Prior to hot vapor-phase etching, the substrate may be exposed to a first silicon-containing gas to deposit a silicon-containing material onto the exposed surfaces of the substrate, including exposed surfaces of the dielectric material and the native oxide film. The silicon-containing material is one, which preferentially adheres to the dielectric material, rather than the native oxide film. Thus, a substantially larger amount of the silicon-containing material is deposited onto the exposed dielectric surfaces than the native oxide film. The silicon-containing material deposited onto the exposed dielectric surfaces provides a dielectric protector or inhibitor film, which protects the dielectric material while the native oxide film (and the substantially thinner silicon-containing material overlying the native oxide film) is being removed from the metal-containing surface by the hot vapor-phase etching. In some embodiments, the substrate may be exposed to a second silicon-containing gas, after hot vapor-phase etching is used to remove the native oxide, to remove residues of the hot vapor-phase etching process from the pre-cleaned metal-containing surface.

As noted above and described in more detail below, the techniques disclosed herein provide native oxide removal without plasma-based damage. In some embodiments, the techniques disclosed herein may use a combination of hot vapor hydrofluoric acid (HF) and TMSDMA (N-Trimethylsilyldimethylamine) to pre-clean metal-containing surfaces. Instead of using plasma cleaning, hot vapor HF etching is used to clean metal-containing surfaces, in combination with TMSDMA deposition (or a similar protective chemical) before and/or after the hot vapor HF etching to enable selective metal (e.g., Ru) deposition on the cleaned metal-containing surfaces. While hot vapor HF and TMSDMA are provided herein as example processing gases that can be used to pre-clean metal-containing surfaces, other hot vapor fluorine-containing agents and silicon-containing gases can also be used in the techniques disclosed herein.

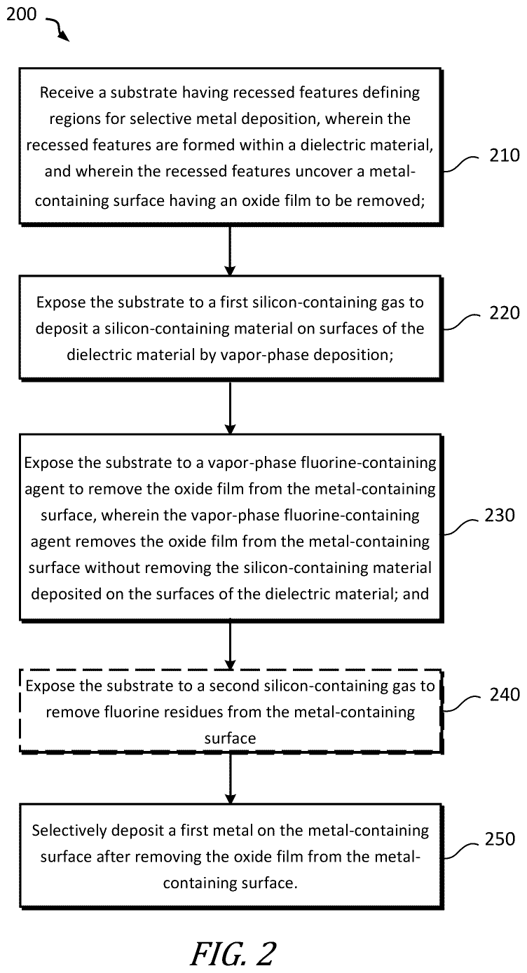

FIG. 2 illustrates one embodiment of a method 200 that utilizes the techniques herein to process a semiconductor substrate, and more specifically, for pre-cleaning a metal-containing surface provided on the substrate prior to depositing a metal material onto the metal-containing surface. The embodiment of the method 200 shown in FIG. 2 includes (in step 210) receiving a substrate having recessed features defining regions for selective metal deposition, where the recessed features are formed within a dielectric material, and where the recessed features uncover a metal-containing surface having an oxide film to be removed. For example, the recessed features can be vias or trenches to be filled with a metal material, such as but not limited to, ruthenium (Ru), Molybdenum (Mo), Cobalt (Co), Tungsten (W) or another low-resistivity metal. In some embodiments, the recessed features are formed within a dielectric material layer (such as a silicon dioxide (SiO2), low-k dielectric or other ILD layer), have a floor with a metal-containing surface (such as, e.g., titanium nitride (TiN)) having an oxide film (such as, e.g., titanium oxide (TiO2)) to be removed from the metal-containing surface.

After receiving the substrate (in step 210), the substrate is exposed to a silicon-containing gas to deposit a silicon-containing material (e.g., a dielectric protector or inhibitor) onto exposed surfaces of the substrate by vapor-phase deposition (in step 220). The substrate can be exposed to a wide variety of silicon-containing gases in step 220 including, but not limited to, hexamethyldisilazane (HMDS), tetramethyldisiloxane (TMDS), dimethylsilane dimethylamine (DMSDMA), N-(Trimethylsilyl)dimethylamine (TMSDMA), bis(dimethylamino) dimethylsilane (BDMADMS), N,O-bis(trimethylsilyl)trifluoroacetamide (BSTFA) or trimethylsilane (TMS). The silicon-containing material is deposited in step 220 onto exposed surfaces of the dielectric material and exposed surfaces of the oxide film. For example, TMSDMA preferentially adheres to silicon dioxide (SiO2). While some TMSDMA material can be deposited on the TiN, coverage is typically poor, resulting in a substantially thinner layer of TMSDMA formed on the TiN than the SiO2.

Next, the substrate is exposed to a vapor-phase fluorine-containing agent to remove the oxide film from the metal-containing surface (in step 230) without removing the silicon-containing material deposited onto the exposed surfaces of the dielectric material. During the hot vapor-phase etching step (step 230), the temperature of the substrate is held above approximately 100 degrees Celsius (° C.), or another temperature sufficiently high, to prevent the fluorine-containing agent from etching the SiO2. In some embodiments, the substrate temperature may be held above approximately 200° C., and more particularly, between 200-250° C. during the hot vapor-phase etching step (step 230) to enable the hot vapor fluorine-containing agent to remove the oxide film from the metal-containing material without attacking or etching the exposed surfaces of the dielectric material. A wide variety of fluorine-containing agents may be used in the hot vapor-phase etching step (step 230). Examples of fluorine-containing agents include, but are not limited to, hydrofluoric acid (HF), nitrogen trifluoride (NF3), tungsten hexafluoride (WF6), or other fluorine-containing compounds.

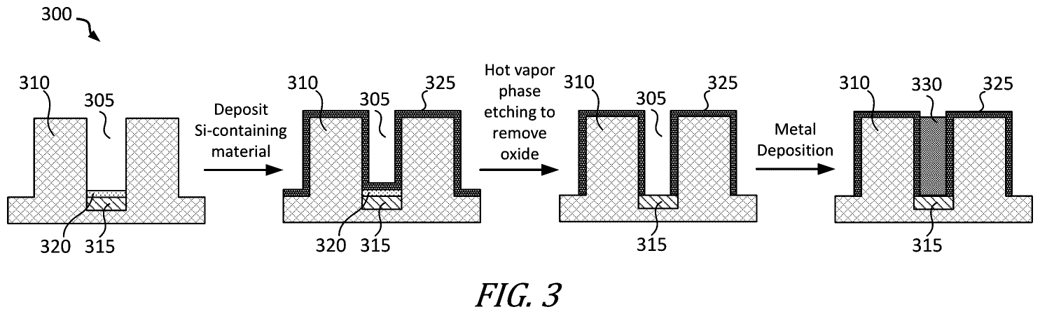

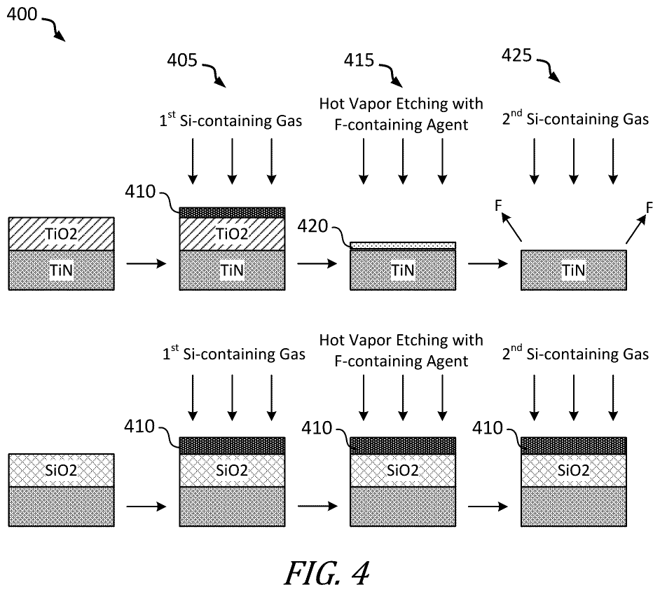

In some embodiments, a first metal is selectively deposited on the metal-containing surface (in step 250) after the oxide film is removed from the metal-containing surface (in step 230). As shown in FIG. 3 and described in more detail below, a film of silicon-containing material (for example, TMSDMA) remains on the dielectric surfaces to protect the dielectric surfaces during the metal deposition step. As shown in FIG. 4 and described in more detail below, TMSDMA can also help with scavenging fluorine residues (or other residues) from the metal-containing surface prior to selectively depositing the first metal on the metal-containing surface (in step 250). The first metal can be, for example, Ruthenium (Ru), Molybdenum (Mo), Cobalt (Co), Tungsten (W), other metals, combinations thereof, etc.

In some embodiments, the substrate may be exposed to a second silicon-containing gas to remove fluorine residues (or other residues) from the metal-containing surface (in step 240). In addition to removing the fluorine residues from the metal-containing surface, the second silicon-containing gas may also recover or restore portions of the dielectric material that may be damaged during hot vapor etching.

A wide variety of silicon-containing gases may be used in steps 220 and 240 of the method 200. In some embodiments, for example, the silicon-containing gases can include, but are not limited to, an alkyl silane, an alkoxysilane, an alkyl alkoxysilane, an alkyl siloxane, an alkoxysiloxane, an alkyl alkoxysiloxane, an aryl silane, an acyl silane, an aryl siloxane, an acyl siloxane, a silazane, and other alkyl amine silanes or any combination thereof. In some embodiments, for example, the silicon-containing gases may include, for example, hexamethyldisilazane (HMDS), 1,1,3,3-tetramethyldisiloxane (TMDS), dimethylsilane dimethylamine (DMSDMA), N-(Trimethylsilyl)dimethylamine (TMSDMA), bis(dimethylamino) dimethylsilane (BDMADMS), N,O-bis(trimethylsilyl)trifluoroacetamide (BSTFA), and trimethylsilane (TMS). In one example implementation of the method 200, TMSDMA may be utilized in steps 220 and 240 as the silicon-containing gas.

In some embodiments, a reactant gas may be added to the second silicon-containing gas (in step 240) to assist in removing fluorine residues (or other residues) remaining on the metal-containing surface prior to selectively depositing the first metal on the metal-containing surface (in step 250). In some embodiments, the reactant gas may contain a methyl group (—CH3). For example, the reactant gas may be selected from N,O-bis(trimethylsilyl)trifluoroacetamide (BSTFA) and trimethylsilane (TMS). In other embodiments, the reactant gas may be dichlorosilane (DCS).

In some embodiments, the processing gas(es) used in step 240 may be a silicon-containing gas having a methyl group. In addition to removing fluorine residues from the metal-containing surface (in step 240), a silicon-containing processing gas containing a methyl group recovers (restores) a low-k film's damaged portion, which may be caused by etching or ashing during the hot vapor-phase etching step. Thus, a silicon-containing gas containing a methyl group (—CH3) may be used as the processing gas (in step 240). For example, the processing gas having the methyl group may be a silylating agent such as TMSDMA (N-(Trimethylsilyl)dimethylamine), DMSDMA (Dimethylsilyldimethylamine), TMDS (1,1,3,3-Tetramethyldisilazane), TMS (Trimethylsilane), BSTFA (N,O-Bis(trimethylsilyl) trifluoroacetamide), or BDMADMS (Bis(dimethylamino) dimethylsilane).

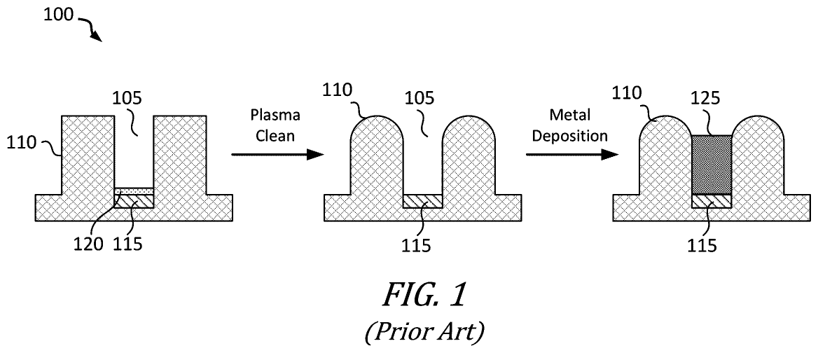

FIG. 3 illustrates one example of an improved process flow 300 that utilizes the techniques shown in FIG. 2 to pre-clean a metal-containing surface before selectively depositing a metal material onto the metal-containing surface. Like the conventional process flow 100 shown in FIG. 1, the improved process flow 300 shown in FIG. 3 is performed on a substrate having recessed feature(s) 305 formed within a dielectric material 310. A first metal material 315, having a native oxide film 320 formed thereon, is formed at the bottom of the recessed feature(s) 305. In one example implementation of the process flow 300, dielectric material 310 is a low-k dielectric, such as silicon dioxide (SiO2), the first metal material 315 is titanium nitride (TiN) and the native oxide film 320 is titanium oxide (TiO2).

In the process flow 300, the substrate is exposed to a first silicon-containing gas to deposit a silicon-containing material 325 onto the exposed surfaces of the dielectric material 310 and the native oxide film 320. After depositing the silicon-containing material 325, the process flow 300 utilizes hot vapor-phase etching to remove the native oxide film 320 to clean and expose the underlying first metal material 315. As shown in FIG. 3, the silicon-containing material 325 protects the dielectric material 310 during hot vapor-phase etching by preventing the fluorine-containing agent (for example, HF) from attacking, or at least substantially etching, the dielectric material 310. After the native oxide film 320 is removed from the surface of the first metal material 315, a second metal material 330 is deposited on the first metal material 315 to fill the recessed feature(s) 305. In some embodiments (not shown), the substrate may be exposed to a second silicon-containing gas to remove residues (for example, fluorine residues) from the first metal material 315 and restore any portions of the dielectric material 310 damaged during hot vapor-phase etching prior to depositing the second metal material 330. In one example implementation of the process flow 300, the first silicon-containing gas and/or the second silicon-containing gas comprise TMSDMA and the fluorine-containing agent comprises hydrofluoric acid. It is noted, however, that other silicon-containing gases and fluorine-containing agents can also be utilized.

FIG. 4 illustrates a simplified process flow 400 that utilizes the techniques disclosed herein. As shown in FIG. 4, hot vapor-phase etching with a fluorine-containing agent (for example, HF) can be used to selectively etch native oxide (e.g., TiO2) from titanium nitride (TiN) and other materials that develop a native oxide. Hot vapor HF (and other hot vapor-phase fluorinated gases) will not etch silicon dioxide (and other low-k materials) when a silicon-containing material (such as, e.g., TMSDMA) is provided on the substrate surface as a dielectric protector or inhibitor. TMSDMA can be used to help protect dielectric surfaces before and/or after hot vapor HF etching, and to remove any fluorine residue that remains on the TiN surface as a result of such etching.

In the process flow 400 shown in FIG. 4, the substrate surface is exposed to a first silicon-containing gas (such as, e.g., TMSDMA) in step 405 to deposit a silicon-containing material layer 410 on the exposed native oxide (TiO2) and dielectric (SiO2) surfaces. The substrate surface is exposed to hot vapor-phase etching with a fluorine-containing agent (such as, HF) in step 415 to remove the native oxide (TiO2) film from the underlying TiN layer. Because a substantially thicker silicon-containing material layer 410 is deposited (in step 405) on the dielectric (SiO2) surface compared to the native oxide (TiO2) surface, the hot vapor-phase etching step (step 415) completely removes the native oxide (TiO2) film from the underlying TiN layer without removing the silicon-containing material layer 410 deposited on the dielectric (SiO2) surface. As shown in FIG. 4, there is a minimal amount of fluorine (F) residue 420 remaining on the TiN surface after hot vapor-phase etching. The fluorine residue 420 is removed from the TiN surface by exposing the substrate surface to a second silicon-containing gas (such as, e.g., TMSDMA) in step 425. Thus, in the process flow 400 shown in FIG. 4, adding a silicon-containing material layer 410 prior to hot vapor-phase etching in step 415 can help protect the dielectric (SiO2) surfaces during etching and during the subsequent metal filling step. Exposing the TiN and SiO2 surfaces to a second silicon-containing gas after hot vapor-phase etching, and before metal filling, removes fluorine residues 420 from the TiN surface and restores the SiO2 surface before a metal material is deposited onto the TiN surface.

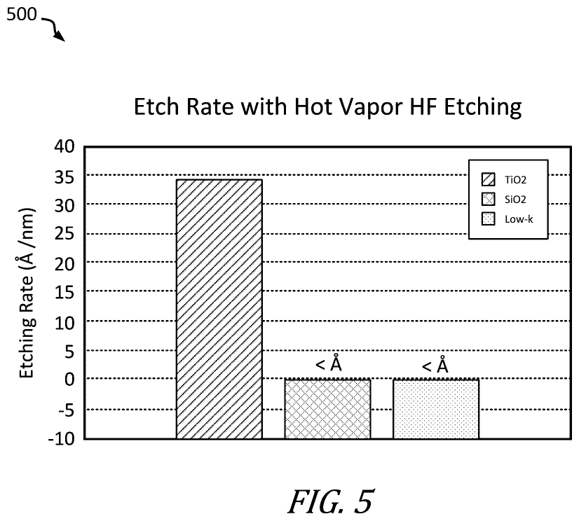

FIG. 5 is a graph 500 illustrating an example etch rate (expressed in A/nm (Angstroms per minute)) of TiO2, SiO2 and other low-k dielectrics during hot vapor-phase etching with hydrofluoric acid (HF). While hot vapor HF etching provides a TiO2 etch rate of approximately 34 Å/nm, the graph 500 shows no substantial etching (e.g., <A) of SiO2 and other low-k dielectrics by HF.

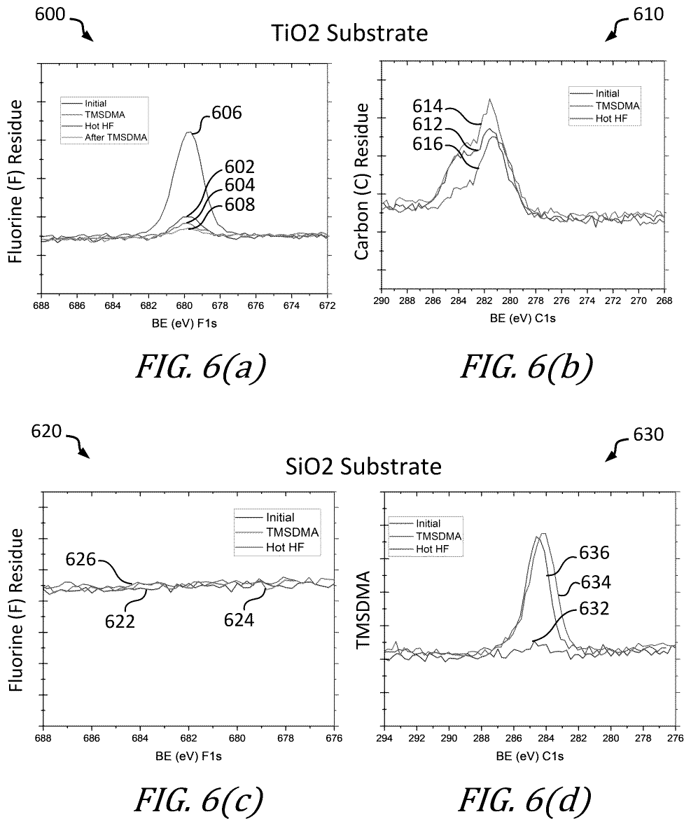

FIGS. 6(a)-6(d) provide various graphs of corresponding material amounts detected on a TiO2 substrate and a SiO2 substrate during one embodiment of the pre-cleaning treatment described herein. The graph 600 shown in FIG. 6(a), for example, illustrates the amount of fluorine (F) residue detected on a TiO2 substrate before the pre-cleaning treatment (initial, line 602), after a first exposure to TMSDMA (TMSDMA, line 604), after hot vapor HF etching (Hot HF, line 606) and after a second exposure to TMSDMA (After TMSDMA, line 608). As shown in the graph 600, the fluorine residues that remain on the TiO2 substrate after hot vapor HF etching are removed when the substrate is re-exposed to TMSDMA.

The graph 610 shown in FIG. 6(b) illustrates the amount of carbon (C) residue detected on a TiO2 substrate before the pre-cleaning treatment (initial, line 612), after exposure to TMSDMA (TMSDMA, line 614) and after hot vapor HF etching (Hot HF, line 616). As shown in the graph 610, there is comparable carbon residue on the TiO2 substrate from prior to treatment to after hot vapor HF etching.

The graph 620 shown in FIG. 6(c) illustrates the amount of fluorine (F) residue detected on a SiO2 substrate before the pre-cleaning treatment (initial, line 622), after a first exposure to TMSDMA (TMSDMA, line 624), after hot vapor HF etching (Hot HF, line 626). Unlike the graph 600, the graph 620 shows that fluorine residues do not remain on the SiO2 substrate after hot vapor HF etching.

The graph 630 shown in FIG. 6(d) illustrates the amount of TMSDMA detected on a SiO2 substrate before the pre-cleaning treatment (initial, line 632), after a first exposure to TMSDMA (TMSDMA, line 634), after hot vapor HF etching (Hot HF, line 636). As shown in graph 630, TMSDMA remains on the SiO2 substrate after hot vapor HF etching.

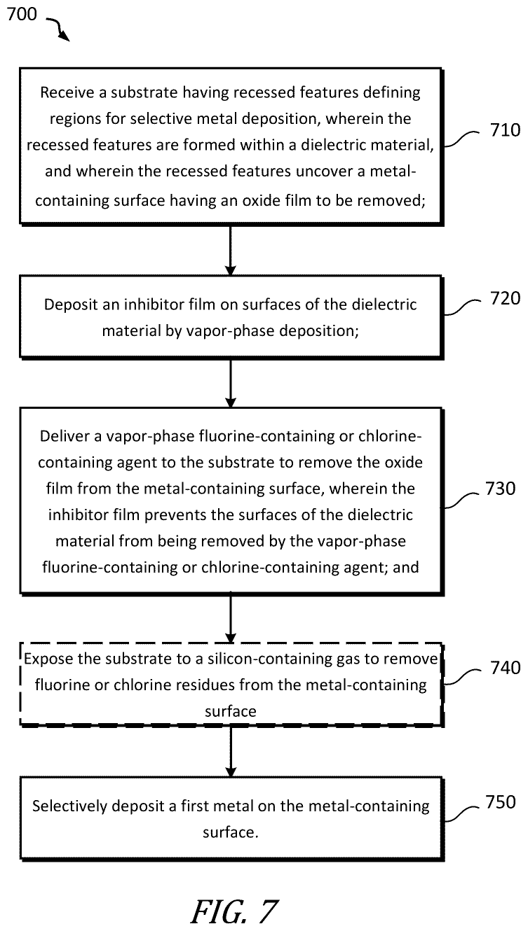

FIG. 7 illustrates another embodiment of a method 700 that utilizes the techniques herein to process a semiconductor substrate, and more specifically, for pre-cleaning a metal-containing surface provided on the substrate prior to depositing a metal material onto the metal-containing surface. Like the method 200 shown in FIG. 2, the method 700 shown in FIG. 7 includes (in step 710) receiving a substrate having recessed features defining regions for selective metal deposition, where the recessed features are formed within a dielectric material, and where the recessed features uncover a metal-containing surface having an oxide film to be removed.

After receiving the substrate (in step 710), the method 700 deposits an inhibitor film on surfaces of the dielectric material by vapor-phase deposition (in step 720) prior to delivering a vapor-phase fluorine-containing or chlorine-containing agent to the substrate to remove the oxide film from the metal-containing surface (in step 730). The inhibitor film deposited (in step 720) prevents the surfaces of the dielectric material from being removed by the vapor-phase fluorine-containing or chlorine-containing agent (in step 730). In one embodiment, the inhibitor film may be deposited (in step 720) by exposing the substrate to a first silicon-containing gas, such as TMSDMA.

A wide variety of vapor-phase fluorine-containing and chlorine-containing agents can be used in step 730 to remove the oxide film from the metal-containing surface. Examples of fluorine-containing agents include, but are not limited to, hydrofluoric acid (HF), nitrogen trifluoride (NF3), tungsten hexafluoride (WF6) and other fluorine-containing compounds. Examples of chlorine-containing agents include, but are not limited to, tungsten pentachloride (WCl5), hydrochloric acid (HCl), chlorine (Cl2), boron trichloride (BCl3) and other chlorine containing agents.

In some embodiments, the substrate may be held at a temperature above 100° C. to prevent the vapor-phase fluorine-containing or chlorine-containing agent from etching the exposed surfaces of the dielectric material (in step 730). In some embodiments, the substrate temperature may be above 200° C., and more particularly, between 200-250° C. during step 730 to enable the vapor-phase fluorine-containing or chlorine-containing agent to remove the oxide film from the metal-containing surface without attacking or substantially etching the exposed surfaces of the dielectric material.

In some embodiments, method 700 may selectively deposit a first metal on the metal-containing surface (in step 750) after the oxide film is removed from the metal-containing surface (in step 730). As noted above, the first metal selectively deposited in step 750 can be a low-resistivity metal, such as Ruthenium (Ru), Molybdenum (Mo), Cobalt (Co), Tungsten (W), other metals, combinations thereof, etc.

In some embodiments, method 700 may expose the substrate to a second silicon-containing gas, such as TMSDMA, to remove fluorine or chlorine residues from the metal-containing surface (in step 740) before selectively depositing the first metal on the metal-containing surface (in step 750). In addition to removing the fluorine or chlorine residues from the metal-containing surface, the second silicon-containing gas may also be used to recover or restore portions of the dielectric material that may be damaged during the oxide removal step (in step 730).

A wide variety of silicon-containing gases can be used in steps 720 and 740 of the method 700. For example, the first silicon-containing gas and the second silicon-containing gas can be selected from a group comprising hexamethyldisilazane (HMDS), tetramethyldisiloxane (TMDS), dimethylsilane dimethylamine (DMSDMA), N-(Trimethylsilyl)dimethylamine (TMSDMA), bis(dimethylamino) dimethylsilane (BDMADMS), N,O-bis(trimethylsilyl)trifluoroacetamide (BSTFA), and trimethylsilane (TMS).

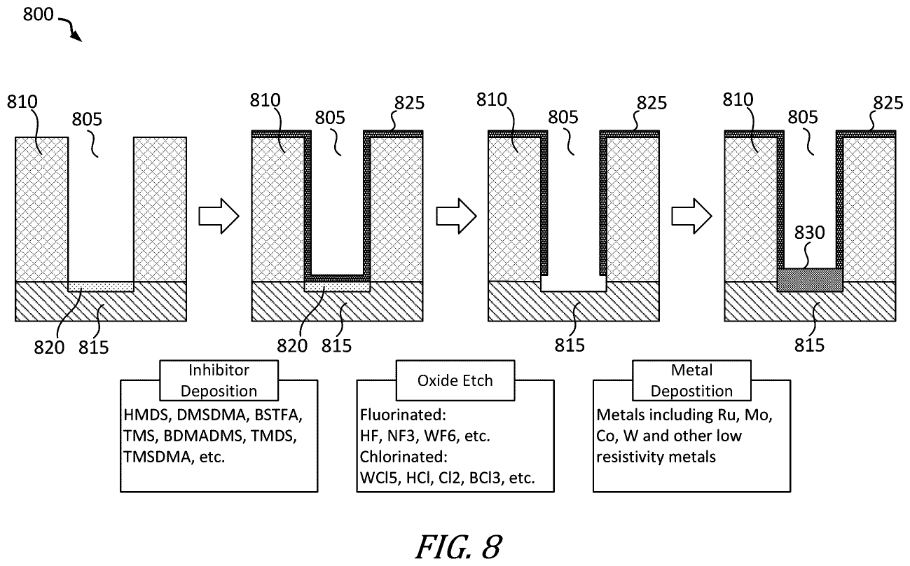

FIG. 8 illustrates another example of an improved process flow 800 that utilizes the techniques shown in FIG. 7 to pre-clean a metal-containing surface before selectively depositing a metal material onto the metal-containing surface. A cross-section of a substrate segment is shown in FIG. 8 having recessed feature(s) 805, which can be a trench or via for a contact, formed within a dielectric material 810. The dielectric material 810 may be a low-k material, SiO2, or other dielectric. In the embodiment shown in FIG. 8, an underlying layer of TiN 815 is uncovered by the recessed feature(s) 805 formed within the dielectric material 810. The uncovered region of TiN 815 (or other metal-containing underlying layer/pad) has a layer or film of native oxide 820 formed thereon, which needs to be removed to improve selective deposition of a metal thereon.

In the process flow 800, an inhibitor film 825 or silicon-containing material is deposited on the substrate. There are several inhibitor options listed in FIG. 8 that can be used (for example, HMDS, DMSDMA, BSTFA, TMS, BDMADMS, TMDS, TMSDMA, etc.). The inhibitor film 825 preferentially coats the dielectric surfaces, with less coverage on the metal-containing surfaces. Next, an oxide etch step is executed to remove the native oxide 820 from the underlying layer of TiN 815. As shown in FIG. 8, the oxide etch step may use hot vapor-phase fluorine-containing agents (such as, e.g., HF, NF3, WF6, or other fluorine-containing compounds) or hot vapor-phase chlorine-containing agents (such as, e.g., WCl5, HCl, Cl2, BCl3 or other chlorine containing compounds) to remove the native oxide 820 from the TiN 815 surface. The result of the oxide etch step is removing or cleaning the native oxide 820 without damaging the dielectric material 810 structures. After the native oxide 820 is removed from the underlying layer of TiN 815, a selective metal deposition step can be executed (using, e.g., Ru, Mo, Co, W, or other low-resistivity metals) to fill the bottom of the recessed feature(s) 805 with a metal material 830. Any number of metal precursors can be used to assist with the selective metal deposition. As shown in FIG. 8, the inhibitor film 825 remains on the dielectric material 810 surfaces as a protective layer during the oxide etch and the subsequently performed metal deposition step.

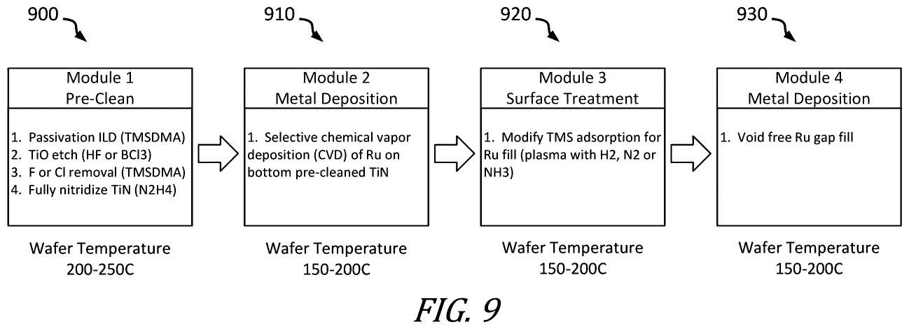

FIG. 9 shows processing details for an example semiconductor fabrication process that utilizes a plurality of modules to process a semiconductor substrate. The modules shown in FIG. 9 includes a Pre-Clean module (Module 1) 900 for cleaning a metal-containing surface provided on the semiconductor substrate, a Metal Deposition module (Module 2) 910 for depositing a metal material on the pre-cleaned metal-containing surface, a Surface Treatment module (Module 3) 920 for treating a surface of the deposited metal material, and a Metal Deposition module (Module 4) 930 for completing the deposition of the metal material. It is noted that the Metal Deposition module (Module 2) 910 and the Metal Deposition module (Module 4) 930 may be the same module. FIG. 9 also provides example wafer processing temperatures that may be utilized for pre-cleaning, metal deposition and surface treatment. Although the example process shown in FIG. 9 shows processing details for pre-cleaning a TiN surface prior to depositing a Ru material on the TiN surface, one skilled in the art would understand how the processing details may be adjusted to pre-clean other metal-containing surfaces prior to depositing other low-resistivity metals on the TiN surface.

As shown in FIG. 9, a number of processing steps may be performed within the Pre-Clean module 900 to pre-clean, or remove the native oxide from, the metal-containing surface before a metal material is deposited onto the metal-containing surface (in Module 2). As noted above, an inhibitor film or silicon-containing material (such as TMSDMA) can be deposited onto the substrate surface and used as a passivation interlayer dielectric (ILD), or protection ILD, to inhibit damage to dielectric material during the native oxide etch. After the inhibitor film is deposited, a hot vapor HF or BCl3 etch may be performed within the Pre-Clean module 900 to remove the native oxide (TiO2) from the TiN surface. Next, the semiconductor substrate may be exposed to TMSDMA to remove fluorine or chlorine residues from the TiN surface before exposing the substrate to a nitrogen-containing gas (e.g., N2H4) to fully nitridize the TiN surface. In some embodiments, the pre-cleaning processing steps may be performed at a substrate temperature of about 200-250° C.

After pre-cleaning, various processing steps may be performed within the Metal Deposition module 910/930 and the Surface Treatment module 920 to selectively deposit a metal material (such as Ru) on the pre-cleaned TiN surface. For example, selective chemical vapor deposition (CVD) can be performed within the Metal Deposition module 910/930 to deposit Ru on the pre-cleaned TiN surface. The Ru CVD processing step may be performed at a substrate temperature of about 150-200° C. After the initial Ru deposition, the substrate may be exposed to a plasma (containing, e.g., hydrogen (H2), nitrogen (N2) or ammonia (NH3)) to pre-treat the Ru surface with a surface modifier that increases metal deposition selectivity. For example, the Ru surface pre-treatment may subject the substrate to the plasma to modify TMS adsorption and/or remove metal nuclei on the Ru surface before completing the Ru deposition in the Metal Deposition module 910/930 to provide a void free Ru gap fill.

In some embodiments, the selective vapor deposition of low-resistivity metal on the target metal surfaces in the Metal Deposition module 910/930 and the removing metal nuclei on particular surfaces in the Surface Treatment module 920 may be repeated until an opening or recessed feature is sufficiently filled with low-resistivity metal. In some embodiments, self-assembled monolayers (SAMs) can also be used in the Surface Treatment module 920 to assist with selective metal deposition. The metal deposition and surface treatment processing steps may be performed at a lower substrate temperature than that used for pre-cleaning. For example, metal deposition and surface treatment processing steps may be performed at a substrate temperature of about 150-200° C., as shown in FIG. 9.

In the preceding description, specific details have been set forth, such as particular processing gases that can be used in some embodiments to pre-clean a metal-containing surface on a semiconductor substrate. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

1. A method of processing a substrate, the method comprising:
receiving a substrate having recessed features defining regions for selective metal deposition, wherein the recessed features are formed within a dielectric material, and wherein the recessed features uncover a metal-containing surface having an oxide film to be removed;
exposing the substrate to a first silicon-containing gas to deposit a silicon-containing material on surfaces of the dielectric material by vapor-phase deposition;
exposing the substrate to a vapor-phase fluorine-containing agent to remove the oxide film from the metal-containing surface, wherein the vapor-phase fluorine-containing agent removes the oxide film from the metal-containing surface without removing the silicon-containing material deposited on the surfaces of the dielectric material; and
selectively depositing a first metal on the metal-containing surface after removing the oxide film from the metal-containing surface.

2. The method of claim 1, wherein the vapor-phase fluorine-containing agent is selected from a group comprising hydrofluoric acid (HF), nitrogen trifluoride (NF3), tungsten hexafluoride (WF6) and other fluorine-containing agents.

3. The method of claim 1, wherein during said exposing the substrate to the vapor-phase fluorine-containing agent, the substrate is held at a temperature above approximately 100 degrees Celsius to prevent the vapor-phase fluorine-containing agent from etching the surfaces of the dielectric material.

4. The method of claim 1, wherein the silicon-containing material protects the surfaces of the dielectric material during: (a) said exposing the substrate to the vapor-phase fluorine-containing agent to remove the oxide film from the metal-containing surface, and (b) said selectively depositing the first metal on the metal-containing surface.

5. The method of claim 1, wherein after said exposing the substrate to the vapor-phase fluorine-containing agent and before said selectively depositing the first metal on the metal-containing surface, the method further comprises exposing the substrate to a second silicon-containing gas to remove fluorine residues from the metal-containing surface.

6. The method of claim 5, wherein the first silicon-containing gas and the second silicon-containing gas are each selected from a group comprising hexamethyldisilazane (HMDS), tetramethyldisiloxane (TMDS), dimethylsilane dimethylamine (DMSDMA), N-(Trimethylsilyl)dimethylamine (TMSDMA), bis(dimethylamino) dimethylsilane (BDMADMS), N,O-bis(trimethylsilyl)trifluoroacetamide (BSTFA), and trimethylsilane (TMS).

7. The method of claim 5, wherein the first silicon-containing gas and the second silicon-containing gas each include N-(Trimethylsilyl)dimethylamine (TMSDMA).

8. The method of claim 5, wherein said exposing the substrate to the second silicon-containing gas restores portions of the dielectric material that are damaged during said exposing the substrate to the vapor-phase fluorine-containing agent.

9. The method of claim 1, wherein the metal-containing surface is titanium nitride (TiN) and the oxide film is titanium oxide (TiO2).

10. The method of claim 1, wherein the first metal is Ruthenium (Ru), Molybdenum (Mo), Cobalt (Co) or Tungsten (W).

11. A method of processing a substrate, the method comprising:
receiving a substrate having recessed features defining regions for selective metal deposition, wherein the recessed features are formed within a dielectric material, and wherein the recessed features uncover a metal-containing surface having an oxide film to be removed;
depositing an inhibitor film on surfaces of the dielectric material by vapor-phase deposition;
delivering a vapor-phase fluorine-containing or chlorine-containing agent to the substrate to remove the oxide film from the metal-containing surface, wherein the inhibitor film prevents the surfaces of the dielectric material from being removed by the vapor-phase fluorine-containing or chlorine-containing agent; and
selectively depositing a first metal on the metal-containing surface.

12. The method of claim 11, wherein the vapor-phase fluorine-containing or chlorine-containing agent is selected from a group comprising hydrofluoric acid (HF), nitrogen trifluoride (NF3), tungsten hexafluoride (WF6), tungsten pentachloride (WCl5), hydrochloric acid (HCl), chlorine (Cl2), boron trichloride (BCl3) and other fluorine-containing or chlorine-containing agents.

13. The method of claim 11, wherein the substrate is held at a temperature above approximately 100 degrees Celsius during said delivering the vapor-phase fluorine-containing or chlorine-containing agent to the substrate.

14. The method of claim 11, wherein the inhibitor film protects the surfaces of the dielectric material during: (a) said delivering the vapor-phase fluorine-containing or chlorine-containing agent to the substrate to remove the oxide film from the metal-containing surface, and (b) said selectively depositing the first metal on the metal-containing surface.

15. The method of claim 11, wherein said depositing the inhibitor film comprises exposing the substrate to a first silicon-containing gas to deposit the inhibitor film on the surfaces of the dielectric material.

16. The method of claim 14, wherein after said delivering the vapor-phase fluorine-containing or chlorine-containing agent and before said selectively depositing the first metal on the metal-containing surface, the method further comprises exposing the substrate to a second silicon-containing gas to remove fluorine or chlorine residues from the metal-containing surface.

17. The method of claim 16, wherein the first silicon-containing gas and the second silicon-containing gas are each selected from a group comprising hexamethyldisilazane (HMDS), tetramethyldisiloxane (TMDS), dimethylsilane dimethylamine (DMSDMA), N-(Trimethylsilyl)dimethylamine (TMSDMA), bis(dimethylamino) dimethylsilane (BDMADMS), N,O-bis(trimethylsilyl)trifluoroacetamide (BSTFA), and trimethylsilane (TMS).

18. The method of claim 17, wherein the first silicon-containing gas and the second silicon-containing gas each include N-(Trimethylsilyl)dimethylamine (TMSDMA).

19. The method of claim 11, wherein the metal-containing surface is titanium nitride (TiN) and the oxide film is titanium oxide (TiO2).

20. The method of claim 11, wherein the first metal is Ruthenium (Ru), Molybdenum (Mo), Cobalt (Co) or Tungsten (W).
